(19) United States
(12) Patent Application Publication
(10) Pub. No.: US 2013/0193311 A1
(43) Pub. Date: Aug. 1, 2013

(54) SOLID-STATE IMAGING DEVICE AND IMAGING APPARATUS

(71) Applicant: Panasonic Corporation, Osaka (JP)

(72) Inventor: SHINJI YOSHIDA, Shiga (JP)

(73) Assignee: Panasonic Corporation, Osaka (JP)

(21) Appl. No.: 13/798,247

(22) Filed: Mar. 13, 2013

Related U.S. Application Data
(63) Continuation of application No. PCT/JP2011/004781, filed on Aug. 29, 2011.

(30) Foreign Application Priority Data
Sep. 27, 2010 (JP) 2010-215896

(51) Int. Cl. H01L 27/146

(52) U.S. Cl. CPC H01L 27/14625
USPC 250/208.1

(57) ABSTRACT

The solid-state imaging device includes an imaging region having pixel units two-dimensionally arranged, each of the pixel units including a photodiode formed on a semiconductor substrate. The imaging region includes, as a unit of arrangement, a pixel block having four of the pixel units arranged in a two-by-two matrix. The pixel block includes a red pixel detecting a red signal, a blue pixel detecting a blue signal, a white pixel detecting a first luminance signal, and another white pixel detecting a second luminance signal. A light attenuation filter is provided above the other white pixel to reduce transmittance of light in a visible light region.

### CROSS REFERENCE TO RELATED APPLICATIONS

This is a continuation application of PCT International Application No. PCT/JP2011/004781 filed on Aug. 29, 2011 designating the United States of America, which is based on and claims priority of Japanese Patent Application No. 2010-215896 filed on Sep. 27, 2010. The entire disclosures of the above-identified applications, including the specifications, drawings and claims are incorporated herein by reference in their entirety.

### FIELD

The present invention relates to a solid-state imaging device and an imaging apparatus included in a digital still camera.

### BACKGROUND

A typical principle for a solid-state imaging device to obtain a color image is to provide a color filter above each pixel to transmit a specific wavelength band, detect color signals that are different for each pixel, and synthesize the different color signals through signal processing so as to reconstruct the signals into an image. Hence, light arriving at each pixel has an unnecessary wavelength band removed by the color filter above the pixel; however, the amount of the light that arrives at the pixel is smaller than the total amount of light that arrives at an imaging area. Patent Literature 1 (PTL 1) discloses a technique to utilize, for some pixels, light which is not dispersed by the color filter and detect a wide transmissive wavelength band so as to increase the sensitivity of the pixels.

FIG. 15 shows a schematic view of a conventional solid-state imaging device illustrated in PTL 1. A solid-state imaging device 300 shown in FIG. 15 includes a solid-state imaging device 312, an infrared cut-off filter layer 313, and a color filter group 314. The infrared cut-off filter layer 313 has an opening part 313a which transmits visible light and infrared light, and a non-opening part 313b which transmits visible light and blocks infrared light. The color filter group 314 includes a filter 314G which transmits green, a filter 314R which transmits red, and a filter 314B which transmits blue, and divides a visible light region into R, G, and B components. The infrared cut-off filter layer 313 and the color filter group 314 are integrated into one piece and provided above the solid-state imaging device 312. The solid-state imaging device 312 causes a wavelength region pixel 312A to detect a wide wavelength region component including the visible light and the infrared light that have passed thorough a filter 314W (or a part with no filter is provided) in the color filter group 314 and the opening part 313a. Then, the solid-state imaging device 312 generates a luminance signal from the detected signal. Furthermore, the solid-state imaging device 312 causes a red pixel 312R, a green pixel 312G, and a blue pixel 312B to respectively detect an R component, a G component, and a B component which pass though a filter 314G, a filter 314R, a filter 314B, and the non-opening part 313b. Then, the solid-state imaging device 312 generates color difference signals from the detected color signals. Hence, the solid-state imaging device 312 causes each detecting unit to, separately or at once, obtain a signal component only having a dispersed wavelength region component and a non-spectral wide wavelength region component, which allows the solid-state imaging device 312 to perform highly-sensitive image capturing.

Patent Literature 2 (PTL 2) discloses a solid-state imaging device which: achieves higher sensitivity using a white pixel, makes it possible to handle strong incident light, and improves an output signal range for each color pixel. FIG. 16 shows a schematic view of a pixel block included in a solid-state imaging device illustrated in PTL 2. A solid-state imaging device 400 shown in FIG. 16 has a pixel block including a white photoelectric converting device 420W, and light-shielded photoelectric converting devices 420LS1 and 420LS2. In other words, one pixel block includes the white photoelectric converting device 420W and the light-shielded photoelectric converting devices 420LS1 and 420LS2 that are provided to one of a red photoelectric converting device 420R, a green photoelectric converting device 420G, and a blue photoelectric converting device 420B. In one pixel block, the white photoelectric converting device 420W is electrically connected to the light-shielded photoelectric converting devices 420LS1 and 420LS2. Moreover, an on-chip lens 421 is provided only above the red photoelectric converting device 420R, the green photoelectric converting device 420G, the blue photoelectric converting device 420B, and the white photoelectric converting device 420W each having an opening to the light.

### CITATION LIST

### Patent Literature

[PTL 1] Japanese Unexamined Patent Application Publication No. 2007-329380
[PTL 2] Japanese Unexamined Patent Application Publication No. 2009-206210

### SUMMARY

### Technical Problem

In the structure of the solid-state imaging device 300 shown in FIG. 15, the wavelength region pixel 312A that detects a wide wavelength region component is a highly sensitive pixel. The wavelength region pixel 312A, however, is saturated excessively faster than spectral pixels for R, G, and B components. Hence, the solid-state imaging device 300 has difficulty in imaging under high lighting intensity. This means that the dynamic range becomes lower as the saturation speed becomes faster, which are common problems to be solved in achieving high sensitivity through the detection of a non-spectral signal and a wide wavelength region component signal.

Furthermore, a typical technique to keep a non-spectral pixel from being saturated is to adjust light amount using a shutter and an aperture. Such a technique inevitably causes a decrease in weak signals from spectral pixels such as R signals and B signals, which results in the reduction in the S/N ratio. Moreover, in the structure shown in FIG. 15, a dielectric laminated film for the non-opening part 313b performs dispersion by the reflection of light having a specific wavelength. This causes a problem of aliasing such as ghost and lens flare.

In contrast, in the structure of the solid-state imaging device 400 shown in FIG. 16, photoelectrons leaking out of the white photoelectric converting device 420W are stored in the light-shielded photoelectric converting devices 420LS1 and 420LS2. Actually, this feature contributes to increasing in photoelectric conversion region and in saturation level of a white signal, leading to higher sensitivity and a wider dynamic range. However, such a feature requires a light shielding pixel. The light shielding pixel decreases the pixel aperture ratio of a photoelectric converting device, and becomes an obstacle to implementing a high-sensitivity solid-state imaging device. Furthermore, an area for the light shielding pixel needs to be secured in the imaging region, which causes a difficulty in making the solid-state imaging device 400 finer with more pixels. Consequently, the solid-state imaging device 400 fails to achieve both higher sensitivity and a wider dynamic range without decreasing the aperture ratio.

The present invention is conceived in view of the above problems and aims to provide a solid-state imaging apparatus which achieves a wider dynamic range without decreasing the aperture ratio, and includes a highly sensitive white pixel that makes imaging possible under high lighting intensity.

### Solution to Problem

In order to solve the above problems, a solid-state imaging device according to an implementation of the present invention includes an imaging region having pixel units two-dimensionally arranged, each of the pixel units including a photodiode formed on a semiconductor substrate. The imaging region includes, as a unit of arrangement, a pixel block having four of the pixel units arranged in a two-by-two matrix, the pixel block includes: a first pixel unit which detects a first color signal; a second pixel unit which detects a second color signal which is different from the first color signal; a third pixel unit which detects a first luminance signal; and a fourth pixel unit which detects a second luminance signal, a color filter is provided above each of the first pixel unit and the second pixel unit to selectively transmit light having a wavelength band corresponding to a desired color signal, and a light attenuation filter is provided above the fourth pixel unit to reduce transmittance of light in a visible light region, so that light sensitivity of the third pixel unit is different from light sensitivity of the fourth pixel unit.

In the above feature, the saturation speed of the fourth pixel unit is slower than that of the third pixel unit. Hence the first luminance signal detected by the third pixel unit and the second luminance signal detected by the fourth pixel unit are used as luminance signals of the pixel block. Such luminance signals make it possible for the pixel block to be saturated as slow as the fourth pixel unit. This allows the solid-state imaging device to achieve both high sensitivity and a wide dynamic range.

Preferably, the light sensitivity of the fourth pixel unit is higher than or equal to spectral sensitivity of either the first pixel unit or the second pixel unit whichever has lower spectral sensitivity, and the transmittance of light of the light attenuation filter is set so that the light sensitivity of the fourth pixel unit is higher than or equal to the lower spectral sensitivity.

In the above feature, saturation is determined only with the luminance signals of the third and fourth pixel units. As far as the fourth pixel unit is not saturated, the first and second pixel units are kept from being saturated. Hence, the feature contributes to reducing the decrease in the S/N ratio of a color signal and obtaining a finer image having higher sensitivity.

Preferably, the third pixel unit and the fourth pixel unit are diagonally arranged in the pixel block.

In the above feature, the arrangement pitch of a luminance signal is set for each row and each column, and contributes to keeping the spatial resolution of the luminance high.

The first color signal may be a blue signal, and the second color signal may be a red signal.

In the above feature, a green signal having the highest luminosity factor is replaced with a luminance signal, so that the error of a color difference signal for a pixel block of the present invention is minimized with respect to an error which occurs to a color difference signal for the Bayer arrangement. Consequently, an image with higher sensitivity and quality can be achieved without decreasing a color S/N ratio

The first color signal is a red signal, and the second color signal is a green signal.

In the above feature, a pixel to detect blue, which has the lowest luminosity factor, is replaced with a white pixel. This contributes to reducing a color S/N ratio and makes it possible to obtain a high-quality image with high sensitivity.

The first color signal is a cyan signal, and the second color signal is a yellow signal.

The color signals are complementary colors for detecting wider wavelength legions and include the two colors—cyan and yellow which include green whose luminosity factor is high. This feature makes it possible to obtain a high-quality image with high sensitivity.

The first color signal or the second color signal may be different between neighboring pixel blocks including the pixel block.

Hence, all the three colors can be arranged in an imaging region, and all the three color-signal pixels abut on each of the third and the fourth pixels that detect a luminance signal. Such a feature contributes to expressing the color component of the luminance signal in high definition, and generating a color image having three colors without subtraction. Consequently, this feature makes it possible to obtain a high-quality image with high sensitivity.

Each of the first color signal and the second color signal may be one of a blue signal, a green signal, and a red signal.

Each of the first color signal and the second color signal may be one of a cyan signal, a yellow signal, and a magenta signal.

Hence, either the primary colors or the three complementary colors are used for the first and the second pixel units. Such a feature contributes to obtaining a high-definition color image.

The light attenuation filter may be either (i) a thin film made of one of amorphous silicon and amorphous germanium or (ii) a carbon thin film.

The thin-film structure can curb reflection and attenuate light over a wide rage of a visible light region. Such a feature contributes to curbing the generation of false color signals caused by color calibration such as subtraction in order to obtain a high-quality image.

In order to solve the above problems, an imaging apparatus according to an implementation of the present invention includes: one of the solid-state imaging devices; and a signal processing device which processes a pixel signal outputted from the pixel unit. The signal processing device adds the first luminance signal to the second luminance signal to generate a luminance signal of the pixel block, the first luminance signal and the second luminance signal being found in the pixel block.

In the above feature, the saturation speed of the fourth pixel unit is slower than that of the third pixel unit. Hence, the sum of the first luminance signal and the second luminance is used as a luminance signal. Such a luminance signal makes it possible for the pixel block to be saturated as slow as the fourth pixel unit. Consequently, this makes it possible to implement a highly sensitive imaging apparatus which is capable of imaging under high lighting intensity, and achieving both higher sensitivity and a wider dynamic range.

In order to solve the above problems, an imaging apparatus according to an implementation of the present invention includes: one of the solid-state imaging devices; and a signal processing device which processes a pixel signal outputted from the pixel unit. The signal processing device includes: a determining unit configured to determine whether or not the first luminance signal in the pixel block saturates within a predetermined period; and a selecting unit which, when the determining unit determines that the first luminance signal is to saturate within the predetermined period, selects the second luminance signal in the pixel block as a luminance signal of the pixel block.

In the above feature, the signal processing device determines whether or not the first luminance signal saturates. In the case where the object has high lighting intensity, the signal processing device can select the second luminance signal as the luminance signal of the pixel block. Since the luminance signal is selected based on the lighting intensity, the imaging apparatus successfully achieves a wide dynamic range and high sensitivity.

### ADVANTAGEOUS EFFECTS

A solid-state imaging device and an imaging apparatus according to an implementation of the present invention include a pixel block which is an arrangement unit in an imaging region. Arranged in the pixel block are two white pixels each differs in sensitivity and color pixels detecting two different color signals. The solid-state imaging device and the imaging apparatus can select between a low-sensitivity luminance signal and a high-sensitivity luminance signal, depending on the lighting intensity of an imaging area. Hence, the solid-state imaging device and the imaging apparatus can obtain a highly sensitive image having a wide dynamic range, and perform imaging under high lighting intensity.

### BRIEF DESCRIPTION OF DRAWINGS

These and other objects, advantages and features of the invention will become apparent from the following description thereof taken in conjunction with the accompanying drawings that illustrate a specific embodiment of the present invention.

FIG. 1 depicts a functional block diagram showing a structure of an imaging apparatus according to Embodiment 1 of the present invention.

FIG. 2 depicts a circuit diagram of a pixel block included in a solid-state imaging device according to Embodiment 1 of the present invention.

FIG. 3 shows a schematic view of a color arrangement in an imaging region of the solid-state imaging device according to Embodiment 1 of the present invention.

FIG. 4 depicts a graph showing a relationship between accumulated electric charge and a charging time observed in each of pixels included in the pixel block of the present invention.

FIG. 5 shows a cross-sectional view of pixels in the imaging region of the solid-state imaging device according to an implementation of the present invention.

FIG. 6 depicts a graph showing a relationship between optical absorptance and film thickness in amorphous silicon.

FIG. 7 depicts a graph showing a transmission spectrum of a color filter used in Embodiment 1.

FIG. 8 is a cross-sectional view of the main section of a low-sensitivity white pixel included in a MOS image sensor according to Embodiment 1 of the present invention.

FIG. 9 shows in cross-section a manufacturing process of the low-sensitivity white pixel included in the MOS image sensor according to Embodiment 1 of the present invention.

FIG. 10 depicts a flowchart showing signal processing performed by an imaging apparatus according to Embodiment 2 of the present invention.

FIG. 11 shows a schematic view of a color arrangement in an imaging region of a solid-state imaging device according to Embodiment 3 of the present invention.

FIG. 12 shows a schematic view of a color arrangement in a pixel block of a solid-state imaging device according to Embodiment 4 of the present invention.

FIG. 13 shows a schematic view of a color arrangement in an imaging region of a solid-state imaging device according to Embodiment 5 of the present invention.

FIG. 14 shows a schematic view of a color arrangement in an imaging region in a modification of a solid-state imaging device according to Embodiment 5 of the present invention.

FIG. 15 shows a schematic view of a conventional solid-state imaging device illustrated in Patent Literature 1.

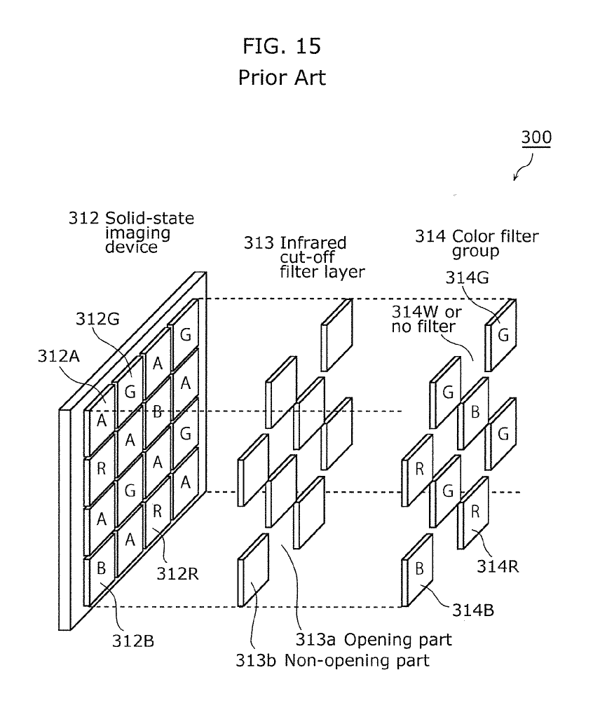

FIG. 16 shows a schematic view of a pixel block included in a solid-state imaging device illustrated in Patent Literature 2.

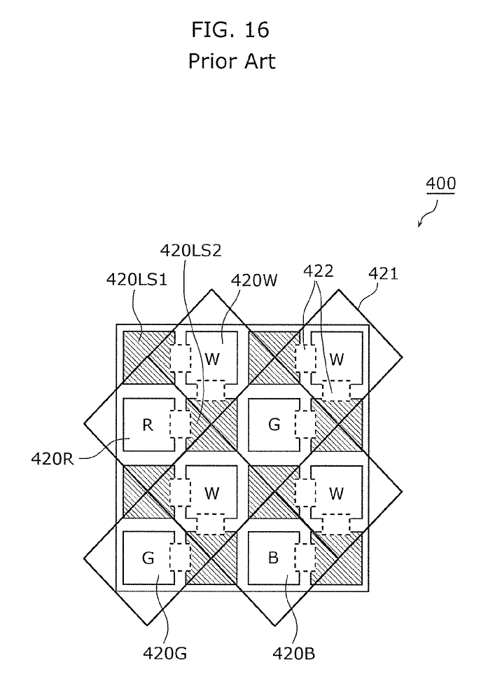

### DESCRIPTION OF EMBODIMENTS

### Embodiment 1

Described hereinafter are the embodiments of the present invention with reference to the drawings.

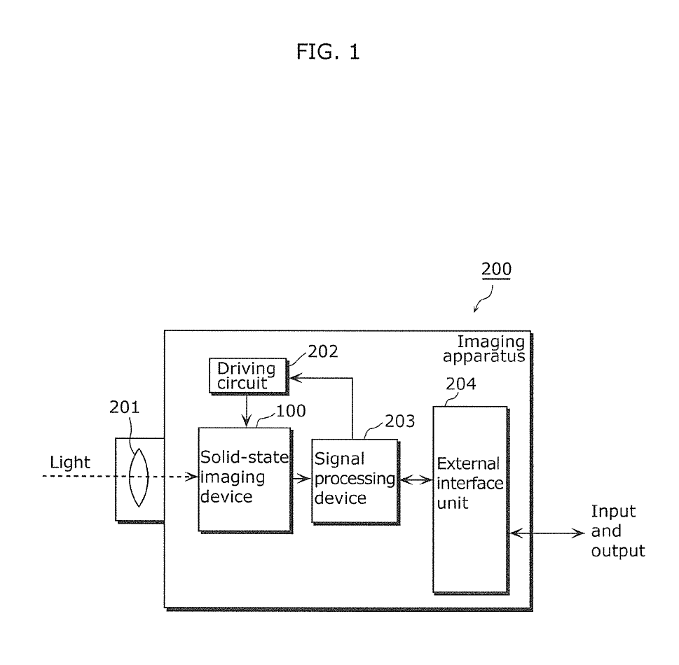

FIG. 1 depicts a functional block diagram showing a structure of an imaging apparatus according to Embodiment 1 of the present invention. An imaging apparatus 200 in FIG. 1 is a digital camera including a solid-state imaging device 100, a lens 201, a driving circuit 202, a signal processing device 203, and an external interface unit 204.

The signal processing device 203 drives the solid-state imaging device 100 using the driving circuit 202, receives an output signal from the solid-state imaging device 100, processes the output signal therein, and sends the processed output signal out via the external interface unit 204.

The imaging region of the solid-state imaging device 100 includes two non-spectral pixels each different in sensitivity. Depending on the lighting intensity of the imaging area, the signal processing device 203 can adjust the amount of light coming to the imaging region either (i) using the sum of the luminance signals of the two non-spectral pixels or (ii) selecting one of the two non-spectral pixels.

Such a structure makes it possible to control, based on brightness of the object, the amount of transmitted light which arrives at the imaging region. As a result, an image can be obtained under high lighting intensity. Moreover, for example, the two non-spectral pixels each different in sensitivity are arranged for each Bayer pattern, so that an object having low brightness and an object having high brightness can be presented in a same image with excellent gradation. Detailed below are the essential parts of the present invention; namely, the solid-state imaging device 100.

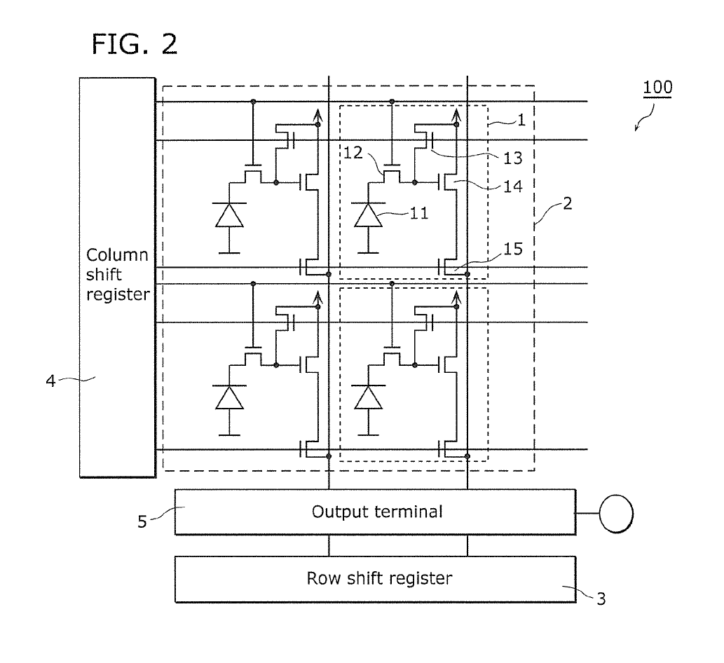

FIG. 2 depicts a circuit diagram of a pixel block included in the solid-state imaging device according to Embodiment 1 of the present invention. The solid-state imaging device 100 includes an imaging region 2 having two-dimensionally arranged unit pixels 1, a row shift register 3 and a column shift register 4 for selecting a pixel signal, and an output terminal 5 for forwarding outside a signal provided from a selected unit pixel 1. Here, each of the unit pixels 1 includes a photoelectric converting unit 11 which is a photo diode.

The imaging region 2 includes multiple unit pixels 1. FIG. 2 shows four unit pixels 1 which form one pixel block. Each of the unit pixels 1 includes a photo diode 11, a transferring transistor 12, a resetting transistor 13, an amplifying transistor 14, and a selecting transistor 15. Each of the transferring transistor 12, the resetting transistor 13, the amplifying transistor 14, and the selecting transistor 15 is a metal-oxide semiconductor (MOS) transistor.

Each pixel block of the solid-state imaging device 100 according to Embodiment 1 of the present invention includes two non-spectral pixels as the unit pixels 1. The two non-spectral pixels are different from each other in light sensitivity.

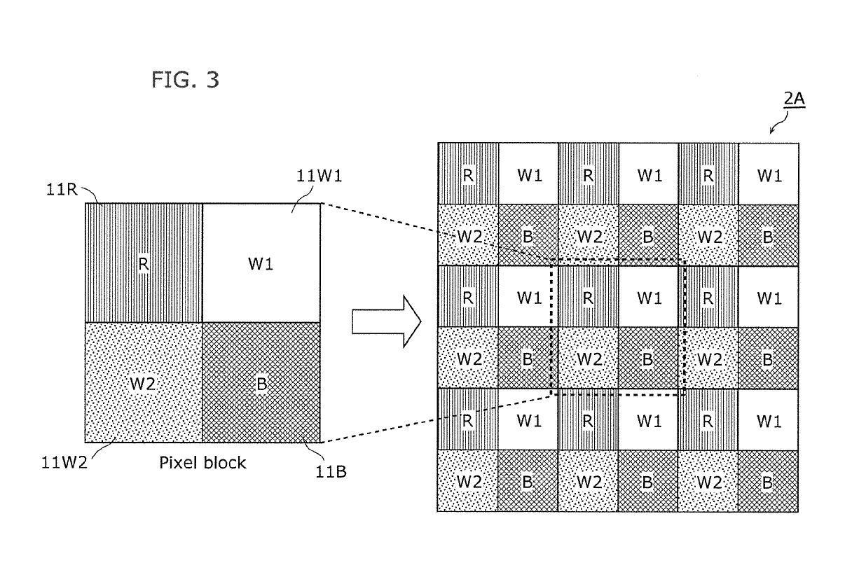

FIG. 3 shows a schematic view of a color arrangement in an imaging region of the solid-state imaging device according to Embodiment 1 of the present invention. In general, a color arrangement to be used for obtaining a color image is referred to as the Bayer arrangement. In the Bayer arrangement, each pixel block has four pixels arranged in a two-by-two matrix: two green pixels are arranged in one diagonal line, and a red pixel and a blue pixel are arranged in the other diagonal line. In contrast, as shown in FIG. 3, the solid-state imaging device 100 according to an implementation of the present invention has the following feature: In each of the pixel blocks, four pixels are arranged in a two-by-two matrix, and two of the four pixels are white pixels which directly detect incident light without separating the incident light into colors.

Specifically, each of the pixel blocks, included in an imaging region 2A of the solid-state imaging device 100, is formed of four unit pixels 1 arranged in a two-by-two matrix. In each pixel block, a red pixel 11R and a blue pixel 11B are arranged in one diagonal line, and white pixels 11W1 and 11W2 are arranged in the other diagonal line. The red pixel 11R is a first pixel unit for detecting a red signal which is a first color signal. The blue pixel 11B is a second pixel unit for detecting a blue signal which is a second color signal. The white pixel 11W1 is a third pixel unit for detecting a first luminance signal. The white pixel 11W2 is a fourth pixel unit for detecting a second luminance signal. Here, the white pixel 11W2 has a light attenuation filter provided above the photo diode 11 so that the light attenuation filter absorbs and attenuates visible light. Hence, the white pixel 11W2 is lower in sensitivity to the visible light than the white pixel 11W1. The details of the light attenuation filter shall be described later.

The structure of the above pixel block allows the photo diodes 11 for the white pixels 11W1 and 11W2 to photoelectrically convert light in a wavelength region which normally rejected by a color filter. Consequently, the sensitivity of the pixel block is successfully increased. Moreover, in the present invention, the white pixels 11W1 and 11W2 are different with each other in sensitivity. Hence, the first luminance signal can be obtained from the white pixel 11W1 and the second luminance signal can be obtained from the white pixel 11W2.

Since the resolution of an image is determined based on the special frequency of a luminance signal, the white pixels 11W1 and 11W2 for obtaining the luminance signal are arranged diagonally. Thus, in the imaging region 2A, pixel units for detecting the luminance signal are arranged for each row and column. This feature makes it possible to acquire higher sensitivity without decreasing the resolution.

Moreover, in Embodiment 1, the first color signal is red and the second color signal is blue. Green signals, which have the highest luminosity factor, are replaced with the first and the second luminance signals. Compared with the error of a color difference signal for the Bayer arrangement, such a feature minimizes the error of a color difference signal of the pixel block. Consequently, higher sensitivity can be achieved without decreasing a color S/N ratio.

The YCbCr color difference space is a color space expressed with one luminance signal Y and two color signals Cb and Cr. When the blue signal is B, the red signal is R, the first luminance signal is W1, and the second luminance signal is W2, Cb is (Y−B) and Cr is obtained by multiplying a specific coefficient with (Y−R). Here, (Y−B) and (Y−R) can be directly created using (W1+W2). Normally, the luminance signal Y in the Bayer arrangement is obtained as follows: Y=0.299×R+0.587×G+0.114×B. Since 60% of the luminance signal Y is a green signal, the green is replaced with the white pixels 11W1 and 11W2 that are luminance pixels, and one of the relationships holds; that is, Y W1, Y W2, or Y (W1+W2). Thus, a color difference signal can be created with the decrease in the S/N ratio reduced.

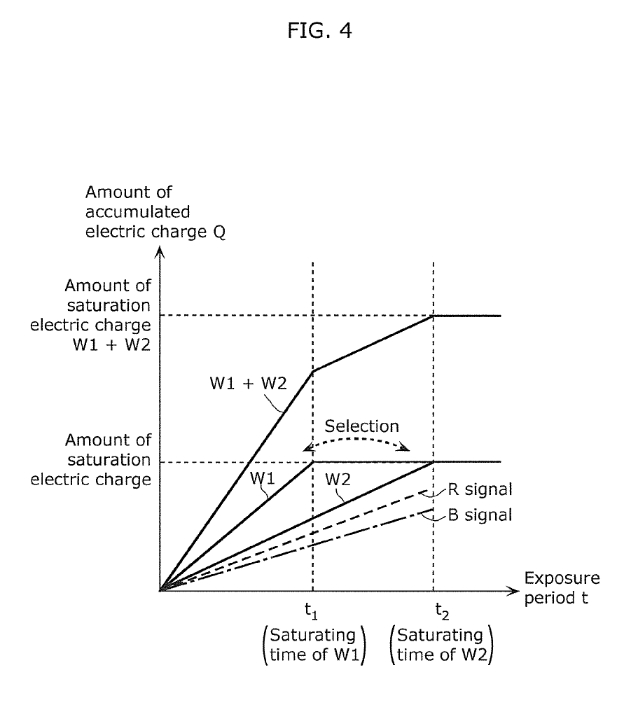

FIG. 4 depicts a graph showing a relationship between accumulated electric charge and a charging time observed in each of pixels included in the pixel block of the present invention. In the graph illustrated in FIG. 4, the abscissa represents an exposure period for each pixel and the ordinate represents accumulated electric charge for each pixel. When t is the exposure period and Q is the amount of accumulated electric charge, the gradient of the graph Q/t is defined as light sensitivity for each pixel. In Embodiment 1 according to an implementation of the present invention, all-optical sensitivity which is the light sensitivity of the white pixel 11W1 is the highest. All-optical sensitivity which is the light sensitivity of the white pixel 11W2 is set lower than that of the white pixel 11W1. The transmittance of the light attenuation filter provided over the white pixel 11W2 is controlled, so that the all-optical sensitivity of the white pixel 11W2 is set higher than spectral sensitivity which is the light sensitivity of the red pixel 11R for detecting a red signal and the blue pixel 11B for detecting a blue pixel. Thanks to the above setting, the red signal and the blue signal do not saturate a region where a luminance signal does not saturate.

In the above setting, saturation is determined only with the luminance signals of the white pixels 11W1 and 11W2. As far as the white pixel 11W2 is not saturated, the red pixel 11R and the blue pixel 11B are kept from being saturated. Hence, the setting contributes to reducing the decrease in the S/N ratio of a color signal and obtaining a finer image having higher sensitivity.

Detailed below is how the white pixel 11W2, which is lower in sensitivity than the white pixel 11W1, can provide a wider dynamic range.

A white pixel is highly sensitive since the pixel does not disperse light but photoelectrically converts light in all wavelength regions. On the contrary, the white pixel reaches its amount of saturation electric charge excessively fast. The graph in FIG. 4 shows that the white pixel 11W1 is saturated with accumulated electric charge at the time n, and the white pixel 11W2 is saturated with accumulated electric charge at the time t2. For example, suppose the time period until the time t is set for an exposure period. Here, the signal levels of the red pixel 11R and the blue pixel 11B are so low that the low signal levels cause a lower S/N ratio.

The signal level of the white pixel 11W2, however, is lower than that of the white pixel 11W1. Thus, when a luminance signal is represented as Y, the relationship Y≈(W1+W2) is established. Hence, substantially, the saturated level of W2 becomes the saturation level of the luminance signal Y. Thus, the exposure period lasting until the luminance signal Y saturates can be made longer. A longer accumulating time for the luminance signal Y provides a greater amount of accumulated electric charge for the red pixel 11R and the blue pixel 11B, which contributes to improving the S/N ratio for the entire pixel block.

The signal processing device 203 calculates a luminance signal in (W1+W2)—that is a summed signal made of a luminance signal W1 and a luminance signal W2—based on a difference in characteristics between the above-described white pixels 11W1 and the 11W2. Then, by either one of the following: calculating the ratio of a color signal component included in the calculated luminance signal or using signal intensities, obtained from the white pixels 11W1 and 11W2, for a red signal for the red pixel 11R and a blue signal for the blue pixel 11B, the S/N ratio of a generated color image can be improved.

It is noted that, in Embodiment 1, the signal processing device 203 is included in the imaging apparatus 200. Instead, the signal processing device 203 may be included in the solid-state imaging device 100, and the solid-state imaging device 100 may process a luminance signal of a pixel block.

Compared with the all-optical sensitivity of the white pixel 11W1, the all-optical sensitivity of the white pixel 11W2 is set lower by the transmittance α. Thus, the second luminance signal W2 is made W2/α, so that the first luminance signal W1 and the second luminance signal W2 have the same light sensitivity. Here, the rate of each color included in a white pixel is represented in Expressions 1 to 3 as follows:

Rate of red Rr: R/(W2/α) (Expression 1)

Rate of blue Br: B/(W2/α) (Expression 2)

Rate of green Gr: [(W2/α)]−R−B]/(W2/α) (Expression 3)

Here, suppose the luminance signal Y for an entire pixel block is (W1+W2). The color intensity for the entire pixel block may be represented in Expressions 4 to 6 as follows:

Red intensity Ri: (W1+W2)×rate of red Rr (Expression 4)

Blue intensity Bi: (W1+W2)×rate of blue Br (Expression 5)

Green intensity Gi: (W1+W2)×rate of green Gr (Expression 6)

In the regular Bayer arrangement, the luminance signal Y is obtained by the product of the signal intensities of R, G, and B and a luminosity factor coefficient. This causes more noise components.

In contrast, the solid-state imaging device 100 according to Embodiment 1 in an implementation of the present invention uses raw data (W1+W2) as a luminance signal. The S/N ratio of the luminance signal is greater than that of the luminance signal for the Bayer arrangement. Such a feature allows a color intensity to be calculated based on the luminance signal having a greater S/N ratio. Hence, the S/N ratio for each color intensity improves. For the green signals, however, the calculation of the rate of green Gr involves subtraction. Hence, the S/N ratio decreases compared with that in the Bayer arrangement. Moreover, color difference signals can be created using the red intensity Ri and the blue intensity Bi. The luminance signal can be re-created as Y=0.299×Ri+0.587×Gi+0.114×Bi, instead of (W1+W2).

In the above feature, the saturation speed of the white pixel 11W2 is slower than that of the white pixel 11W1. Hence, a signal, which is the sum of the first luminance signal W1 and the second luminance signal W2, is used as a luminance signal. Such a luminance signal makes it possible for a pixel block to be saturated as slow as the white pixel 11W2 is. Consequently, this makes it possible to implement a solid-state imaging device and an imaging apparatus capable of imaging under high lighting intensity, the solid-state imaging device achieving both higher sensitivity and a wider dynamic range, and the imaging apparatus being small and highly sensitive.

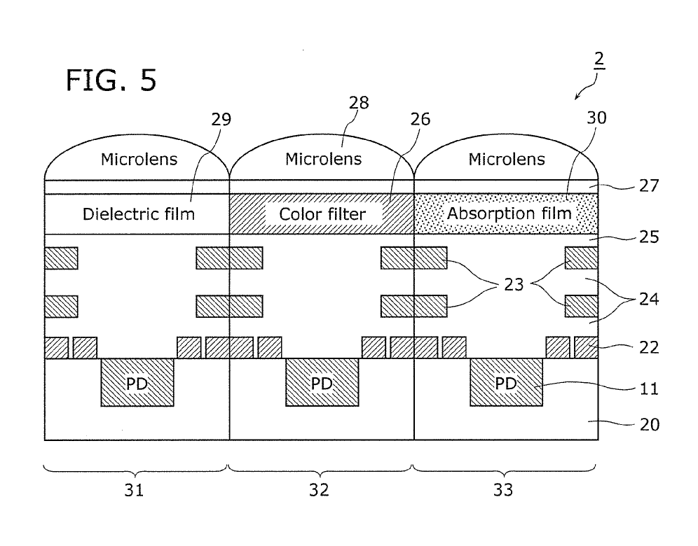

FIG. 5 shows a cross-sectional view of pixels in the imaging region of the solid-state imaging device according to an implementation of the present invention. As described above, the pixel block according to an implementation of the present invention includes three kinds of pixels: a white pixel 31 which corresponds to the white pixel 11W1, color signal detecting pixels 32 each of which corresponds to one of the red pixel 11R and the blue pixel 11B, and a low-sensitivity white pixel 33 which corresponds to the white pixel 11W2. Here, two color signal detecting pixels 32, and one each of the white pixel 31 and the low-sensitivity white pixel 33 form one pixel block. For the sake of convenience, FIG. 5 illustrates the white pixel 31, a color signal detecting pixel 32, and the low-sensitivity white pixel 33 aligned in a strait line. Actually, as shown in FIG. 3, the pixels are arranged in a two-by-two matrix: two color signal detecting pixels 32 are arranged in one diagonal line, and the white pixel 31 and the low-sensitivity white pixel 33 are arranged in the other diagonal line.

The photo diode 11 is formed by ion implantation within the semiconductor substrate 20 made of silicon. On the semiconductor substrate 20, a gate and a gate wire 22 of a transistor are provided. In order to electrically connect the gate and the gate wire 22 with each other, metal wires 23 are provided. Here, the metal wires 23 are separated from each other with an interlayer film 24.

In the white pixel 31, a dielectric film 29 is provided via an interlayer film 25 above a wiring layer including the metal wires 23 and the interlayer film 24. Above the dielectric film 29, a microlens 28 is formed via a planarizing film 27. The white pixel 31 is non spectral, and thus no color filter is provided. Instead the dielectric film 29, which is transparent, is provided in the visible light region. The dielectric film 29 may be, for example, a SiO2 film. This is because the interlayer films 24 and 25 are mainly made of SiO₂, and the dielectric film 29 is desirably made of the same material as that of the interlayer films 24 and 25 to prevent reflection and refraction.

In the color signal detecting pixel 32, a color filter 26 is provided above a wiring layer via the interlayer film 25. Above the color filter 26, a microlens 28 is formed via the planarizing film 27.

In the low-sensitivity white pixel 33, a light absorption film 30 is provided above the wiring layer via the interlayer film 25. Above the light absorption film 30, a microlens 28 is formed via the planarizing film 27. In the above structure, light collected by the microlens 28 passes through one of the dielectric film 29, the color filter 26, and the light absorption film 30, and converted by the photo diode 11 into electricity. Instead of a color filter, the low-sensitivity white pixel 33 includes the light absorption film 30, and causes the film to attenuate the light.

The solid-state imaging device including the above light attenuation filter can control, based on brightness of the object, the amount of transmitted light which arrives at the imaging region. As a result, an image can be obtained under high lighting intensity. Moreover, the solid-state imaging device has the light attenuation filter provided for each pixel block, and successfully captures both of an object having low brightness and an object having high brightness at the same time with excellent gradation.

Described next is the light attenuation filter—the light absorption film 30—provided above the white pixel 11W2. The light attenuation filter according to Embodiment 1 is an amorphous silicon thin film.

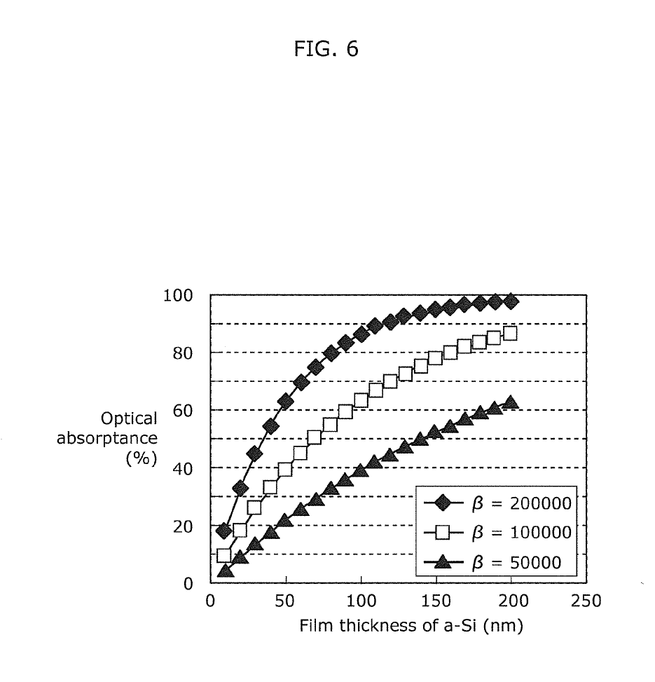

FIG. 6 depicts a graph showing a relationship between optical absorptance and film thickness in amorphous silicon. The amorphous silicon is known for its broad and high light absorption in the wavelength region of a visible light region.

In contrast, crystalline silicon, such as poly-silicon, is known that its light absorption coefficient in the long-wavelength side significantly decreases approximately at 400 nm. Hence, the amorphous silicon is most suitable for the light attenuation filter according to an implementation of the present invention. The amorphous silicon has a significantly high absorption coefficient β of approximately 100000 to 500000, depending on how the amorphous silicon is deposited. The amorphous silicon according to Embodiment 1 is deposited by, for example, sputtering. Here, the absorption coefficient β is approximately 200000.

The graph in FIG. 6 shows that a thin film whose absorption coefficient β is 200000 and film thickness is 150 nm can absorb more than or equal to 95% of light. The light attenuation filter according to an implementation of the present invention needs to be set so that the all-optical sensitivity of the white pixel 11W2 is higher than or equal to the spectral sensitivity of the red pixel 11R and the blue pixel 11B.

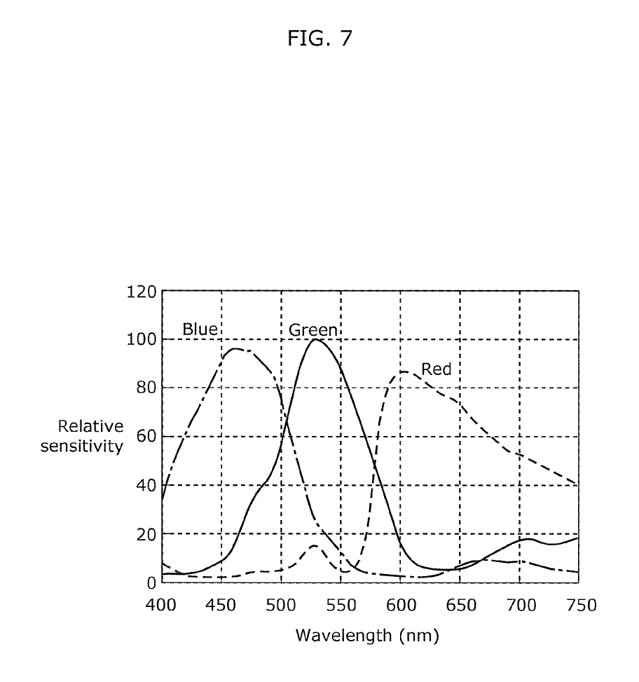

FIG. 7 depicts a graph showing a transmission spectrum of the color filter used in Embodiment 1. Each color signal is approximately one third of the entire light amount. Hence, the optical absorptance of the amorphous silicon is desirably lower than or equal to 66.7%. When β is 200000, the film needs to be thinner than or equal to 55 nm. In Embodiment 1, for example, the amorphous silicon is set for 25 nm in film thickness. Here, the optical absorptance is 40%.

In Embodiment 1, amorphous silicon is used. It is because the light attenuation filter is an absorbent thin film and thus requires a material which achieves broad and high light absorption in the visible light region. Here, amorphous germanium and a carbon thin film are absorbent materials having a narrow bandgap. These materials can be applied as light absorption films.

The above features provide a thin film which curbs optical reflection and attenuates light over a wide range of the visible light region, which contributes to curbing the generation of false color signals caused by color calibration such as subtraction. Consequently, a high-quality image can be obtained.

Described next is an exemplary technique of manufacturing a low-sensitivity white pixel including a light absorption film made of amorphous silicon. The manufacturing technique needs to include a process of forming a light attenuation filter. In Embodiment 1, the amorphous silicon is provided above the topmost wiring layer. Thus, detailed hereinafter is a manufacturing process after the topmost wiring layer.

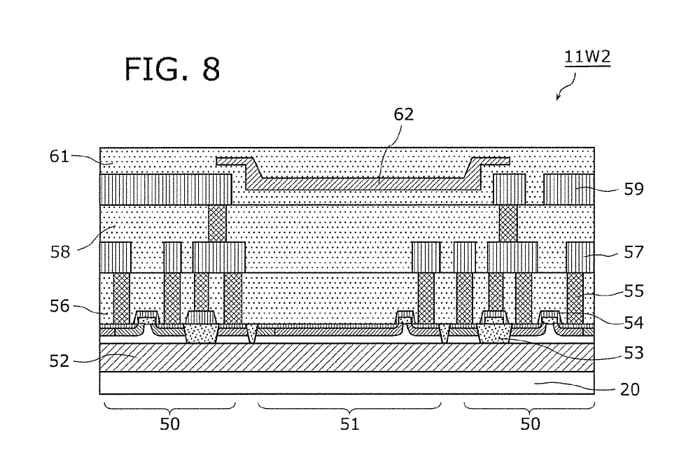

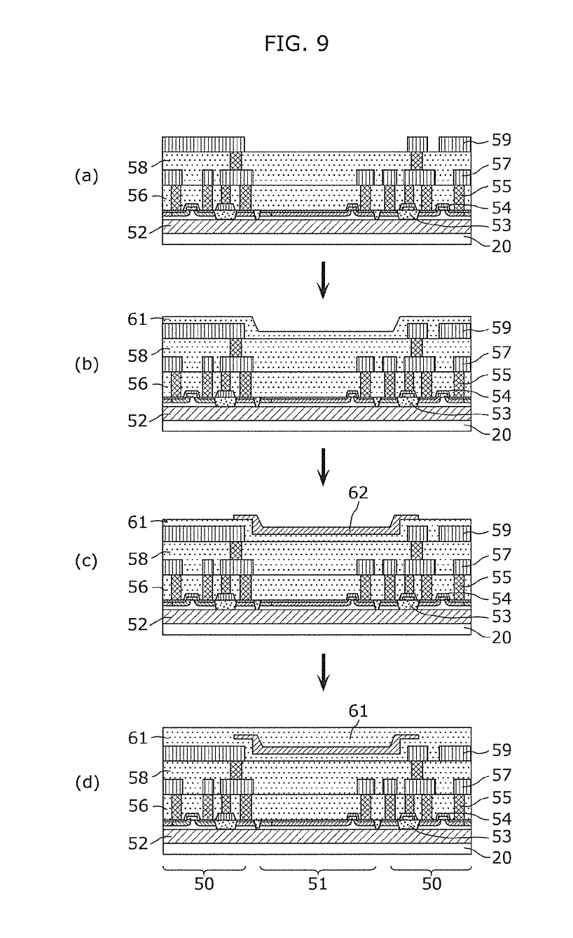

FIG. 8 is a cross-sectional view of the main section of a low-sensitivity white pixel included in a MOS image sensor according to Embodiment 1 of the present invention. FIG. 9 shows in cross-section a manufacturing process of the low-sensitivity white pixel included in the MOS image sensor according to Embodiment 1 of the present invention.

First, as shown in FIG. 8 and the illustration (a) in FIG. 9, a diffusion region 52 is formed on the semiconductor substrate 20 by ion implantation. An imaging region 51 and a peripheral circuit region 50 are formed over the semiconductor substrate 20. A transistor 54 is electrically separated by an element separating portion 53. The transistor 54, for example, is any one of the transferring transistor 12, the resetting transistor 13, the amplifying transistor 14, and the selecting transistors 15 and 17 in FIG. 2. After the transistor 54 is formed, an interlayer insulating film 56, including an insulator such as boron phosphor silicate glass (BPSG), is formed. The interlayer insulating film 56 is planarized by chemical mechanical polishing (CMP) and etchback. Then a contact hole is formed by dry etching and a metal plug 55 is formed by the metal CVD. With the metal plug 55 exposed, aluminum is deposited by sputtering and patterned by dry etching to form a wiring layer 57. Repeating the above process, mufti-layered wiring is formed. The solid-state imaging device according to Embodiment 1 employs two-layer wiring. Hence, over the wiring layer 57 that is the first layer, an interlayer insulating film 58 is formed and planarized. Then a metal plug is formed and a second layer that is a wiring layer 59 is formed.

As shown in the illustration (b) in FIG. 9, described next is a process of forming a light attenuation filter. The BPSG is formed as part of an interlayer insulating film 61.

Then, as shown in the illustration (c) in FIG. 9, amorphous silicon is deposited by sputtering and etched except the portion for an opening of the white pixel 11W2. Hence, an amorphous silicon layer 62 is formed.

Next, as shown in the illustration (d) in FIG. 9, the BPSG is deposited again over the amorphous silicon layer 62 and planarized by the CMP. Thus, the interlayer insulating film 61 is formed.

Then, a microlens is formed on a planarized film formed on the interlayer insulating film 61. Hence, the use of amorphous silicon as a light attenuation filter allows the light attenuation filter to be made thinner at a low temperature. Thus, a silicon processing technique can be used for manufacturing the white pixel. Such a feature allows a solid-state imaging device to be manufactured easily at a low cost.

It is noted that the structure shown in Embodiment 1 is just an example, and the light attenuation filter does not have to be provided above the topmost wiring layer. In other words, the light attenuation filter may be provided in a light path between the microlens and a pixel. For example, when amorphous silicon is deposited between the surface of the silicon substrate and the aluminum wiring in the first layer, no metal with a low melting point is included before the aluminum wiring. Hence, the CVD can also be employed to deposit amorphous silicon.

### Embodiment 2

An imaging apparatus according to Embodiment 2 differs from the imaging apparatus according to Embodiment 1 only in the following points: the signal processing device 203 determines whether or not a luminance signal for the white pixel 11W1 saturate, and selects, as a luminance signal, either the first luminance signal W1 to be detected by the white pixel 11W1 or the second luminance signal W2 to be detected by the white pixel 11W2. Hereinafter, the same points between Embodiment 1 and Embodiment 2 shall be omitted, and only the differences therebetween shall be described.

Since a pixel block included in the solid-state imaging device 100 has white pixels 11W1 and 11W2 each having a different pixel sensitivity, the signal processing device 203 selects as a luminance signal either the first luminance signal W1 or the second luminance signal W2, depending on the lighting intensity of an imaging area. Such a feature makes it possible to implement a wide dynamic range.

The signal processing device 203 includes: a determining unit which determines whether or not the first luminance signal W1 in the pixel block saturates within a predetermined period, and a selecting unit which, when the determining unit determines that the first luminance signal W1 is to saturate within the predetermined period, selects the second luminance signal W2 in the pixel block as a luminance signal for the pixel block.

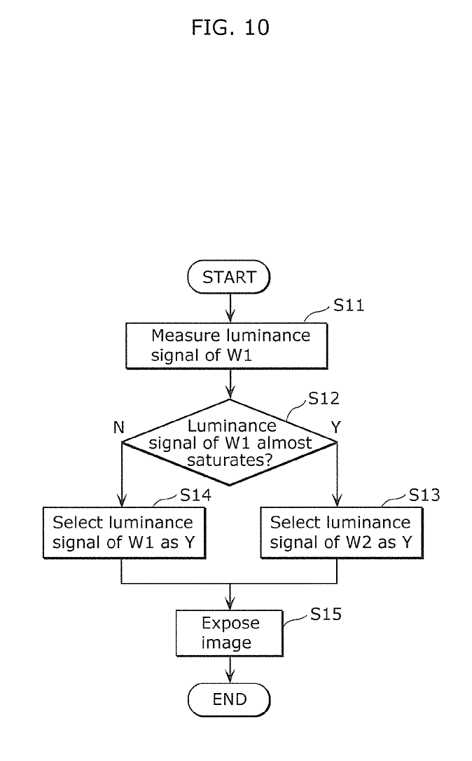

When there are an object with high brightness and an object with low brightness within the same imaging area, for example, the signal processing device 203 can employ as a luminance signal (i) the first luminance signal W1 having high sensitivity in capturing an object with low brightness or (ii) the second luminance signal W2 having low sensitivity in capturing an object with high brightness. Such a feature successfully increases a dynamic range within the same angle of view. Described hereinafter is a signal processing flow for the above feature with reference to FIG. 10.

FIG. 10 depicts a flowchart showing signal processing performed by the imaging apparatus according to Embodiment 2 of the present invention.

First, the signal processing device 203 measures a luminance signal of the white pixel 11W1 for each pixel block (S11).

Next, the determining unit of the signal processing device 203 determines whether or not the W1 in the white pixel 11W1 saturates, based on the pixel sensitivity of the white pixel 11W1 (S12). The determination is made based on the luminance signal measured in Step 11—that is to calculate Q/t in FIG. 4, or light sensitivity.

Here, in the case where the determination shows based on the calculated light sensitivity that the first luminance signal W1 is either to saturate in a necessary exposure period or close to a saturation level (Step S12: Yes), the selecting unit in the signal processing device 203 selects, as the luminance signal, the second luminance signal W2 having low sensitivity (S13). In contrast, in the case where the luminance signal is low since the brightness of the object is low, and the first luminance signal W1 is not to saturate in the necessary exposure period (Step S12: No), the selecting unit 203 selects the first luminance signal W1 having high sensitivity (S14).

Then, the signal processing device 203 causes the solid-state imaging device 100 to capture an object in the necessary exposure period (S15), selects, as the luminance signal, the signal that is selected for each pixel block and found in either the white pixel 11W1 or the white pixel 11W2, and generates a color image. Such a process makes it possible to implement a wide dynamic range.

In the above feature, the signal processing device 203 determines whether or not the first luminance signal W1 to be detected by the white pixel 11W1 saturates. In the case where the lighting intensity is high, the signal processing device 203 selects as the luminance signal the second luminance signal W2 to be detected by the white pixel 11W2. Since the luminance signal is selected based on the lighting intensity, the imaging apparatus successfully achieves a wide dynamic range and high sensitivity.

It is noted that the necessary exposure period is a time period which is long enough to obtain an S/N ratio for pixels having the lowest sensitivity, such as the red pixel 11R and the blue pixel 11B. The user of the imaging apparatus may determine any given necessary exposure period.

The signal processing device 203 in Embodiment 2 is included in the imaging apparatus 200; instead, the signal processing device 203 may be included in the solid-state imaging device, and the solid-state imaging device may execute the above processing of the luminance signal for the pixel block.

### Embodiment 3

A solid-state imaging device according to Embodiment 3 differs from the solid-state imaging device according to Embodiment 1 in the arrangement of unit pixels forming a pixel block. Hereinafter, the same points between Embodiment 1 and Embodiment 3 shall be omitted, and only the differences therebetween shall be described.

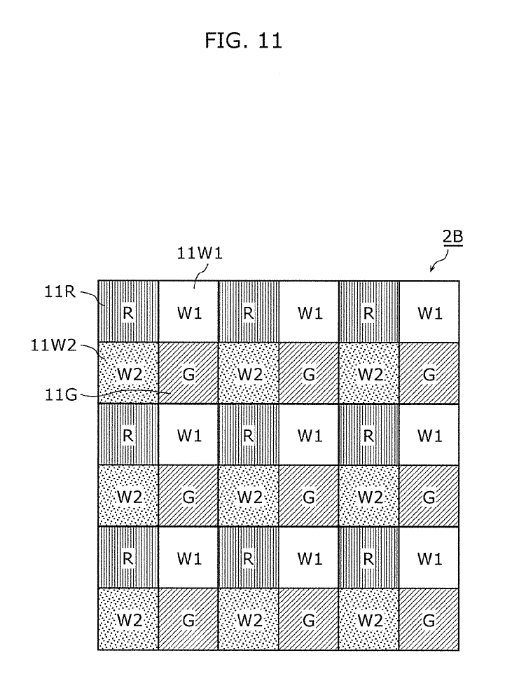

FIG. 11 shows a schematic view of a color arrangement in an imaging region of the solid-state imaging device according to Embodiment 3 of the present invention. A pixel block included in an imaging region 2B shown in FIG. 11 has white pixels instead of a blue pixel and one of green pixels in the Bayer arrangement. As shown in FIG. 11, in each pixel block, four pixels are arranged in a two-by-two matrix, and two of the four pixels are white pixels which directly detect incident light without separating the incident light into colors. Specifically, each of the pixel blocks, included in the imaging region 2B, is formed of the four unit pixels 1 arranged in a two-by-two matrix. In each pixel block, the red pixel 11R and a green pixel 11G are arranged in one diagonal line, and the white pixels 11W1 and 11W2 are arranged in the other diagonal line. The red pixel 11R is a first pixel unit for detecting a red signal which is a first color signal. The green pixel 11G is a second pixel unit for detecting a green signal which is a second color signal. The white pixel 11W1 is a third pixel unit for detecting a first luminance signal. The white pixel 11W2 is a fourth pixel unit for detecting a second luminance signal. Here, the white pixel 11W2 has a light attenuation filter provided over the photo diode 11 so that the light attenuation filter absorbs and attenuates visible light. Hence, the white pixel 11W2 is lower in sensitivity to the visible light than the white pixel 11W1.

The blue pixel has the lowest luminosity factor in a luminance signal. Hence the blue factor having a lower luminosity factor does not need a higher color S/N ratio. Thus, even though the pixel block has the blue pixel, which has a low luminosity factor, replaced with one of the white pixels 11W1 and 11W2 while keeps the green pixel 11G which requires a high color S/N ratio, the solid-state imaging apparatus according to Embodiment 3 can obtain a highly sensitive image while curbing the deterioration of the image. Here, the blue signal is calculated by the subtraction in Expression 7, which subtracts the green and red signals from a white pixel:

Blue signal: B=(W2/α)−G−R (Expression 7)

As described in Embodiment 1, the subtraction increases noise, and thus causes reduction in S/N ratio; however, the subtraction performed to blue having a low luminosity factor can curb deterioration in the reproduction of a color. Such a feature makes it possible to obtain an image having a wide dynamic range and high sensitivity.

In other words, in the above feature, a pixel to detect the blue signal, which has the lowest luminosity factor, is replaced with a white pixel. This contributes to reducing a color S/N ratio and makes it possible to obtain a high-quality image with high sensitivity.

The structure of the above pixel block allows the photo diodes 11 for the white pixels 11W1 and 11W2 to photoelectrically convert light in a wavelength region which normally rejected by a color filter. Consequently, the sensitivity of the pixel block is successfully increased. Moreover, in the present invention, the white pixels 11W1 and 11W2 are different with each other in sensitivity. Hence, the first luminance signal can be obtained from the white pixel 11W1 and the second luminance signal can be obtained from the white pixel 11W2.

Since the resolution of an image is determined based on the special frequency of a luminance signal, the white pixels 11W1 and 11W2 for obtaining the luminance signal are arranged diagonally. Thus, in the imaging region 2B, pixel units for detecting the luminance signal are arranged for each row and column. This feature makes it possible to acquire higher sensitivity without decreasing the resolution.

It is noted that, in Embodiment 3, the white pixels 11W1 and 11W2 are diagonally arranged to maximize the resolution. In the case where the all-optical sensitivity of the white pixel 11W2 having low sensitivity is set equal to the spectral sensitivity of the green pixel 11G, the white pixel 11W1 and the green pixel 11G may be diagonally arranged.

### Embodiment 4

A solid-state imaging device according to Embodiment 4 differs from the solid-state imaging device according to Embodiment in the arrangement of unit pixels forming a pixel block. Hereinafter, the same points between Embodiment 1 and Embodiment 4 shall be omitted, and only the differences therebetween shall be described.

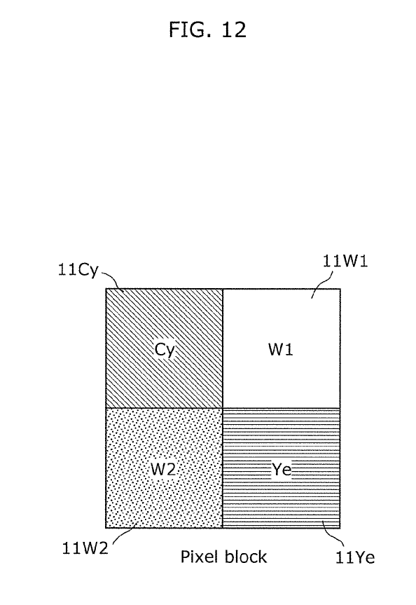

FIG. 12 shows a schematic view of a color arrangement in a pixel block of the solid-state imaging device according to Embodiment 4 of the present invention. The pixel block in FIG. 12 includes a cyan pixel 11Cy and a yellow pixel 11Ye instead of the red pixel 11R and the blue pixel 11B, respectively, in the pixel block illustrated in FIG. 3 of the Embodiment 1.

In other words, the first color signal to be detected by the first pixel unit and the second color signal detected by the second pixel unit are complementary colors. Specifically, the two complementary colors are preferably cyan and yellow, since these colors include a green component having a high luminosity factor.

In the solid-state imaging device according to an implementation of the present invention, white pixels are arranged in a pixel block, and a single pixel block includes pixels each having a totally different sensitivity. These features inevitably cause a sensitivity difference (difference in saturating speed) between a color detecting pixel and a white pixel. In the arrangement of pixel blocks according to Embodiment 4, however, the cyan pixel 11Cy and the yellow pixel 11Ye, which are color detecting pixels, are high in spectral sensitivity since a complementary color has a detection wavelength region wider than that of a primary color. Hence, the sensitivities of a color signal pixel and a white pixel get closer to each other, and the entire sensitivity of the pixel block will be highest. Such a feature makes it possible to obtain a supersensitive image in a high dynamic range.

### Embodiment 5

In Embodiments 1 to 4, one of the three colors included in the Bayer arrangement is replaced with a white pixel. When the pixel block arrangement is changed from the conventional Bayer arrangement to an arrangement in an implementation of the present invention, the arrangement RGB is changed to the arrangement RB+W, the arrangement RGB is changed to the arrangement RG+W, and the arrangement MgCyYe is changed to the arrangement CyYe+W. Here, Mg represents magenta. As found in the above arrangement changes, the pixel block arrangements according to Embodiments 1 to 4 in an implementation of the present invention suffer from unavoidable decrease in color repeatability caused by the lack of one piece of color information. In order to overcome the problem, the special frequency of a color arrangement is reduced and all the three colors are arranged, so that the color repeatability is successfully secured without subtraction.

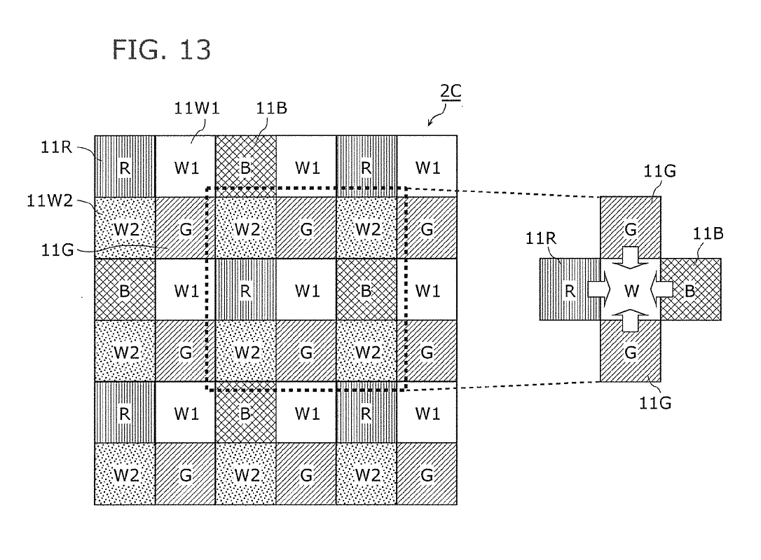

FIG. 13 shows a schematic view of a color arrangement in an imaging region of a solid-state imaging device according to Embodiment 5 of the present invention. An imaging region 2C in FIG. 13 includes two kinds of pixel blocks each having four pixels arranged in a two-by-two matrix. The two kinds of pixel blocks are alternately provided. For example, in a first pixel block, the white pixels 11W1 and 11W2 are arranged in one diagonal line, and the red pixel 11R that is a first pixel unit and the green pixel 11G that is a second pixel unit are arranged in the other diagonal line. In a second pixel block, the white pixels 11W1 and 11W2 are arranged in one diagonal line, and the blue pixel 11B that is a first pixel unit and the green pixel 11G that is a second pixel unit are arranged in the other diagonal line. The first pixel block and the second pixel block neighboring each other and are alternately arranged in a matrix. In other words, the first color signal is different between neighboring pixel blocks.

It is noted that, as a modification of the above arrangements, the first pixel block may include in the other diagonal line the red pixel 11R that is the first pixel unit and the blue pixel 11B that is the second pixel unit, and the second pixel block may include in the other diagonal line the red pixel 11R that is the first pixel unit and the green pixel 11G that is the second pixel unit. In other words, the second color signal is different between neighboring pixel blocks.

The above arrangements allow each of the white pixels 11W1 and 11W2 to abut on all the three color-signal pixels (the red pixel 11R, the green pixel 11G, and the blue pixel 11B). Thanks to the arrangements, the reproduction of color for the first luminance signal W1 and the second luminance signal W2 can be determined based on the proportion of color signals which abut on the white pixels. Hence, a color component, of the white pixel, included in a luminance signal can be expressed in high definition, using neighboring R, B, and two Gs to the white pixel.

For example, when a luminance signal W (W1 or W2) is separated into color components using the raw data of a color signal, the following relationship holds: W=R+B+two Gs. Hence, a color can be added to a white pixel with addition. Thus, the signal processing device 203 can generate a color image for a pixel block without subtraction. Here, the average value of Gs may be employed instead of the two Gs. Taking a luminosity factor into consideration, the following relationship may hold: Y=0.299×R+0.587×G+0.114×B. Here, Y is a luminance signal, R is red intensity, G is green intensity, and B is blue intensity.

In Embodiment 5, the three primary colors RGB are used as color signals; instead, complementary colors such as CyMgYe may also be used.

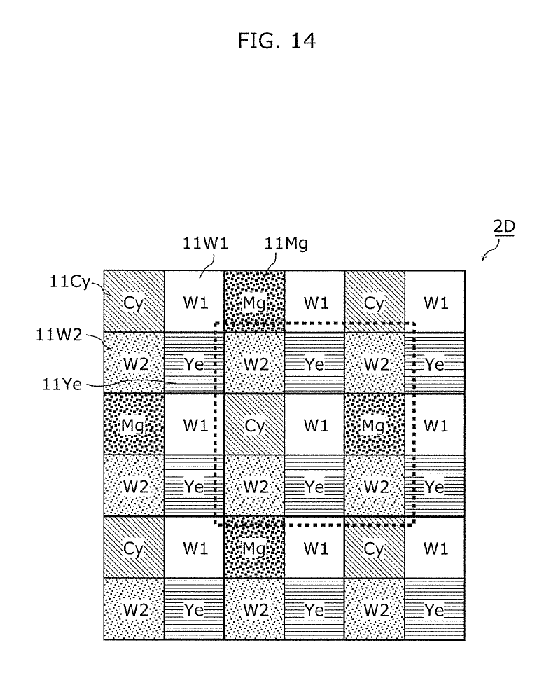

FIG. 14 shows a schematic view of a color arrangement in an imaging region in a modification of the solid-state imaging device according to Embodiment 5 of the present invention. An imaging region 2D in FIG. 14 includes two kinds of pixel blocks each having four pixels arranged in a two-by-two matrix. The two kinds of pixel blocks are alternately provided. The first pixel block includes: the white pixels 11W1 and 11W2 arranged in one diagonal line; and the cyan pixel 11Cy for the first pixel unit and the yellow pixel 11Ye for the second pixel unit arranged in the other diagonal line. The second pixel block includes: the white pixels 11W1 and 11W2 arranged in one diagonal line; and a magenta pixel 11Mg which is the first pixel unit and the yellow pixel 11Ye that is the second pixel unit arranged in the other diagonal line. The first pixel block and the second pixel block are neighboring and are alternately arranged in a matrix. In other words, the first color signal is different between the neighboring blocks. It is noted that the second color signal may be different between the neighboring pixel blocks.

When the color signal pixels are complementary colors as shown in the above arrangements, a wider detection wavelength region is obtained as described in Embodiment 4. Consequently, higher sensitivity can be achieved.

As described in Embodiments 1 to 5, a solid-state imaging device and an imaging apparatus according to an implementation of the present invention have a wide dynamic range. Hence, a camera including the solid-state imaging device and the imaging apparatus is a sophisticated and high-performance one in a small size with a light-amount adjusting capability.

Although only some exemplary embodiments of the present invention have been described in detail above, those skilled in the art will readily appreciate that many modifications are possible in the exemplary embodiments without materially departing from the novel teachings and advantages of the present invention. Accordingly, all such modifications are intended to be included within the scope of the present invention.

It is noted that Embodiment 1 exemplifies a CMOS solid-state imaging device; however, the present invention shall not be defined only for the CMOS solid-state imaging device. In the present invention, a CCD solid-state imaging device is also as effective as the CMOS one.

### INDUSTRIAL APPLICABILITY

The present invention is useful for digital cameras, and is most suitable for solid-state imaging devices and cameras which need to have a wide dynamic range and obtain high quality images.

1. A solid-state imaging device comprising
an imaging region having pixel units two-dimensionally arranged, each of the pixel units including a photodiode formed on a semiconductor substrate,
wherein the imaging region includes, as a unit of arrangement, a pixel block having four of the pixel units arranged in a two-by-two matrix,
the pixel block includes:
a first pixel unit configured to detect a first color signal;
a second pixel unit configured to detect a second color signal which is different from the first color signal;
a third pixel unit configured to detect a first luminance signal; and
a fourth pixel unit configured to detect a second luminance signal,
a color filter is provided above each of the first pixel unit and the second pixel unit to selectively transmit light having a wavelength band corresponding to a desired color signal, and
a light attenuation filter is provided above the fourth pixel unit to reduce transmittance of light in a visible light region, so that light sensitivity of the third pixel unit is different from light sensitivity of the fourth pixel unit.

2. The solid-state imaging device according to claim 1,
wherein the light sensitivity of the fourth pixel unit is higher than or equal to spectral sensitivity of either the first pixel unit or the second pixel unit whichever has lower spectral sensitivity, and
the transmittance of light of the light attenuation filter is set so that the light sensitivity of the fourth pixel unit is higher than or equal to the lower spectral sensitivity.

3. The solid-state imaging device according to claim 1,
wherein the third pixel unit and the fourth pixel unit are diagonally arranged in the pixel block.

4. The solid-state imaging device according to claim 1,
wherein the first color signal is a blue signal, and
the second color signal is a red signal.

5. The solid-state imaging device according to claim 1,
wherein the first color signal is a red signal, and
the second color signal is a green signal.

6. The solid-state imaging device according to claim 1,
wherein the first color signal is a cyan signal, and
the second color signal is a yellow signal.

7. The solid-state imaging device according to claim 1,
wherein the first color signal or the second color signal is different between neighboring pixel blocks including the pixel block.

8. The solid-state imaging device according to claim 7,
wherein each of the first color signal and the second color signal is one of a blue signal, a green signal, and a red signal.

9. The solid-state imaging device according to claim 7,
wherein each of the first color signal and the second color signal is one of a cyan signal, a yellow signal, and a magenta signal.

10. The solid-state imaging device according to claim 1,
wherein the light attenuation filter is either (i) a thin film made of one of amorphous silicon and amorphous germanium or (ii) a carbon thin film.

11. An imaging apparatus comprising:
the solid-state imaging device according to claim 1; and
a signal processing device which processes a pixel signal outputted from the pixel unit,
wherein the signal processing device adds the first luminance signal to the second luminance signal to generate a luminance signal of the pixel block, the first luminance signal and the second luminance signal being found in the pixel block.

12. An imaging apparatus comprising:
the solid-state imaging device according to claim 1; and
a signal processing device which processes a pixel signal outputted from the pixel unit,
wherein the signal processing device includes:
a determining unit configured to determine whether or not the first luminance signal in the pixel block saturates within a predetermined period; and
a selecting unit configured to, when the determining unit determines that the first luminance signal is to saturate within the predetermined period, select the second luminance signal in the pixel block as a luminance signal of the pixel block.
